(19) United States
(12) Patent Application Publication
(10) Pub. No.: US 2026/0310872 A1
(43) Pub. Date: Oct. 8, 2026

(54) TRANSFORMER-BASED END-TO-END HOTSPOT DETECTION METHOD FOR INTEGRATED CIRCUIT LAYOUTS

(71) Applicant: Nanjing University, Nanjing (CN)

(72) Inventors: Ningmu Zou, Nanjing (CN); Wenboo Xu, Nanjing (CN); Yibo Huang, Nanjing (CN); Silin Chen, Nanjing (CN); Kangjian Di, Nanjing (CN); Yufeng Zhang, Nanjing (CN); Yuxiang Fu, Nanjing (CN)

(73) Assignee: Nanjing University, Nanjing (CN)

(21) Appl. No.: 19/534,818

(22) Filed: Feb. 10, 2026

(30) Foreign Application Priority Data
Apr. 7, 2025 (CN) 202510421005.X

(51) Int. Cl. G06F 30/392; G06F 30/31

(52) U.S. Cl. CPC G06F 30/392; G06F 30/31

(57) ABSTRACT

A Transformer-based end-to-end hotspot detection method integrated circuit layouts includes: converting existing integrated circuit layout data into binary image data and storing the converted binary image data, inputting the converted binary image data into a GPU-driven lithography simulator, to obtain a lithographically processed printed image, and performing metric measurement on the post-lithography printed image and original binary image, to obtain positional information of potential hotspots; generating prior lithography information based on the original binary image and the lithographically processed printed image, inputting a trained hotspot detection model into a Transformer-based end-to-end hotspot detector, outputting location information of hotspots, and locating hotspots within the layout. The method is driven by a GPU-accelerated lithography simulator, eliminating the requirement for dataset-dependent hyperparameters, thereby significantly enhancing flexibility and reducing computational resource consumption.

### CROSS REFERENCE TO THE RELATED APPLICATIONS

This application is based upon and claims priority to Chinese Patent Application No. 202510421005.X, filed on Apr. 7, 2025, the entire contents of which are incorporated herein by reference.

### TECHNICAL FIELD

The present invention relates to the technical field of integrated circuit computer-aided design, and particularly to a Transformer-based end-to-end hotspot detection method for integrated circuit layouts.

### BACKGROUND

The rapid advancement of semiconductor technology, particularly the continuous scaling down of transistor feature sizes and the corresponding increase in integrated circuit die dimensions, has created significant challenges in implementing effective design for manufacturability methodologies. Hotspot detection serves as a critical step in design for manufacturability methodologies, enabling pre-lithographic identification of potential defect patterns during integrated circuit layout optimization

Conventional detection methodologies are primarily categorized into two technical approaches: lithography simulation and layout retrieval. The lithography simulation technology is configured to simulate the entire lithographic manufacturing process for the whole chip after each design iteration, thereby enabling accurate detection of hotspots. However, the simulation process is time-consuming and thus not suitable for application in contemporary large-scale integrated circuit manufacturing; and the method identifies hotspot layout segments with similar patterns through matching or clustering operations, based on a layout retrieval technique. However, such methods rely on large-scale layout pattern hotspot libraries and are incapable of detecting hotspots outside the existing library.

With the rapid advancement of semiconductor technology, the continuous miniaturization of integrated circuit components persistently drives the boundaries of current chip fabrication processes. As feature sizes decrease, ensuring the printability of layout designs becomes increasingly challenging, resulting in elevated occurrence rates of manufacturing defects. The challenge is particularly pronounced in critical regions designated as hotspot areas, where defect risks are substantially heightened. Consequently, the accurate and efficient identification of these hotspot regions has become critically important.

Contemporary hotspot detection systems predominantly implement three principal methodologies: lithography simulation, pattern matching, and machine learning-based detection architectures. Conventional lithography simulation methods, while achieving high precision, are prohibitively time-consuming, thereby rendering the methods impractical for implementation in large-scale production environments. In contrast, pattern matching methods identify potential hotspots in a new design by utilizing a set of predetermined hotspot layout patterns. Although the method is faster than traditional lithography simulation, the limitation lies in failing to detect novel or previously unseen hotspots.

However, existing deep learning-based methods in the prior art still suffer from inherent limitations. Existing two-stage hotspot detectors, as exemplified in Chinese Invention Patent Application Publication No. CN117314828A, disclose a method and system for detecting lithography hotspot based on a deep learning-based (Lithography Hotspot Detection (LHD) model. Conventional single-stage hotspot detectors, as exemplified in Chinese Patent Application Publication No. CN118247560A disclosing a lithographic hotspot detection method employing a transformer-CNN dual-domain fusion network, universally rely on anchor-based model frameworks for candidate region generation. Conventional approaches require laborious manual configuration of numerous sensitive hyperparameters and post-processing operations, wherein the hyperparameters encompass anchor box dimensions, aspect ratios, and analogous parameters essential for defining candidate regions in object detection systems. Such methods lack flexibility in adapting to hotspots of varying scales and geometries. Furthermore, Existing methods still require the use of Non-Maximum Suppression (NMS), which means these methods are not end-to-end and consume additional computational resources.

### SUMMARY

To overcome the limitations in prior art, the present invention provides a Transformer-based end-to-end hotspot detection method for integrated circuit layouts.

The present invention provides a Transformer-based end-to-end hotspot detection method integrated circuit layouts, including the following steps:
step 1. converting existing integrated circuit layout data into binary image data and storing the converted binary image data;
step 2. inputting the converted binary image data into a GPU-driven lithography simulator, and outputting a post-lithography printed image and storing;
step 3. constructing a Transformer-based end-to-end hotspot detector, and inputting both the post-lithography printed image and the original binary image into a query vector initialization module for metric measurement, thereby obtaining positional information of potential hotspots, and storing;
step 4. generating prior lithography information based on the original binary image and the post-lithography printed image, constructing a layout training set and a validation set of the layout, and inputting the sets into the Transformer-based end-to-end hotspot detector for model training, thereby obtaining a trained hotspot detection model; and
step 5: inputting an integrated circuit layout under test, according to positional information of potential hotspots in the binary image layout obtained through step 2 and step 3, into the trained hotspot detection model of step 4 for testing; and locating hotspots within the layout.

Preferably, in the step 2, the GPU-driven lithography simulator performs processing operations including:
step 2.1. transferring, in the lithography simulator, spatial information of a mask image to an optical projection system via incident light passing through the mask, and converting an input light intensity distribution into a lithographic intensity distribution on a wafer plane;
step 2.2. converting an aerial image I into a printed pattern Z through the lithography simulator, wherein the printed image represents a post-etch pattern on a semiconductor wafer, by defining etched regions as areas where lithography intensity exceeds a predetermined lithography threshold on the wafer plane, while non-etched regions correspond to areas where the lithography intensity remains below the threshold;
step 2.3. the printed pattern Z is represented as:

$$Z ( x , y ) = {σ}_{Z} ( I ( x , y ) ) = \frac{1}{1 + {e}^{( - α ( I ( x , y ) - {I}_{t h} ) )}}$$

wherein a represents a steepness of a control function, Iₜₕ represents a threshold parameter, configured to control a central inflection point of a Sigmoid function, σ_{Z} denotes a Sigmoid function, configured to input I(x,y), and map the input I(x,y) to an interval of (0,1), thereby forming a smoothed probability value or a normalized output; and
outputting the pattern Z as the post-lithography printed image and performing gradient descent within an iterative learning method.

Preferably, in the step 3, the transformer-based end-to-end hotspot detector sequentially includes: a backbone network, an encoder, a query vector initialization module, a decoder, and a feed-forward neural network;
wherein the backbone network, employing the ResNet50 architecture, is configured to: process an input layout image into a feature map; learn a two-dimensional representation of the input layout image through feature extraction; flatten the extracted features into a high-level activation map; and transmit the high-level activation map to the encoder;
the encoder is a Transformer-based encoder, which is configured to capture global dependencies and spatial relationships in semiconductor layout patterns, generate a new feature map, and transmit the new feature map to the decoder;
the decoder, configured as a Transformer-based decoder, processing N target queries in parallel at each layer via a feature aggregation module, incorporating prior knowledge from lithography simulation into an input of each attention layer, outputting N predictive results, and independently transmitting each of the N prediction results to a feedforward neural network.

Preferably, in the step 3, the query vector initialization module is configured to divide the input post-lithography printed image and the original binary image into non-overlapping blocks, calculate a metric loss for each block, and integrate lithographic simulation prior information into critical components of the Transformer-based end-to-end hotspot detector; wherein the metric loss measure discrepancies between the two images, generate a discrepancy map, and visually emphasize critical regions.

Preferably, in the step 3, the obtaining positional information of potential hotspots includes the following steps:
step 3.1. dividing an image by partitioning both the input original binary image and the post-lithography printed image into a plurality of non-overlapping blocks;
step 3.2. calculating, for each block B(i,j), a pixel value difference at each pixel location within the block:

$${L}_{metric} ( i , j ) = {I}_{input} ( p ) - {I}_{print} ( p ) ;$$

wherein Iᵢₙₚᵤₜ(p) and Iₚᵣᵢₙₜ(p) denote pixel intensities at pixel location p in the input original binary image and the post-lithography printed image, respectively;
step 3.3. calculating a metric loss for each block: calculating the metric loss L_{metric}(i,j) for each block by summing squared differences of all pixels within the block;
step 3.4. constructing a loss map: aggregating metric losses from all blocks, to construct a loss map L_{metric map}, wherein the loss map includes metric loss values of each block;
step 3.5. selecting potential hotspot: identifying, within a loss map, the top k blocks exhibiting the highest loss values as candidate hotspots, and preserving positional information corresponding to the candidate hotspots within the blocks; and
step 3.6. integrating positional prior information: conveying location data of potential hotspot-containing blocks to the decoder as prior knowledge, directing decoder's attention toward regions exhibiting significant lithographic disparitie, thereby enhancing hotspot detection accuracy and operational efficiency;
Preferably, the Transformer-based encoder includes a plurality of Transformer encoder layers sequentially arranged, each Transformer encoder layer includes a multi-head self-attention module and a feed-forward neural network, and introduces a fixed positional encoding;
wherein the multi-head self-attention module is configured to simultaneously attend to distinct partitions of the circuit layout, capture localized geometric patterns and global topological dependencies, and identify hotspots that are non-adjacent but exhibit critical correlations within a global context;
the fixed positional encoding is incorporated into an input of each attention layer and is configured to integrate spatial relationships into the multi-head self-attention module, thereby comprehending layout structures and localizing potential hotspot regions; and
each layer of the Transformer encoder is configured to process the feature sequence in parallel, generate local features integrated with global contextual information, and provide the generated features to the decoder.

Preferably, the feed-forward neural network preferably includes: a three-layer multilayer perceptron including ReLU activation functions, a network with a hidden dimension of d, followed by a linear projection layer configured to predict center coordinates, height, and width of a bounding box for each hotspot, and the linear projection layer is configured to output class labels via a softmax function.

Preferably, in the step 5, the locating hotspots in the chip layout to be tested includes the following sub-steps:
step 5.1. repeating step 1 in the integrated circuit layout under test, to obtain binary image data;
step 5.2. repeating step 2 in the integrated circuit layout under test, to obtain a post-lithography printed image;
step 5.3. repeating step 3 in the integrated circuit layout under test, to obtain prior lithography information; and
step 5.4. inputting both the original binary image and prior lithography information into the trained hotspot detection model established in step 4, outputting positional coordinates of hotspots and annotating bounding boxes as the final detection results generated by the hotspot detection model

The present invention further provides an electronic device, including:
one or more processors; and
a storage device having one or more programs stored thereon;
wherein the one or more programs, when executed by the one or more processors, cause the one or more processors to implement the Transformer-based end-to-end chip layout hotspot detection method.

The present disclosure also provides a computer-readable storage medium having a computer program stored thereon, wherein the computer program, when executed by a processor, causes the processor to implement the steps of the Transformer-based end-to-end chip layout hotspot detection method.

Compared to the prior art, the aforementioned technical solution employed by the present invention achieves the following technical effects:
1. The end-to-end hotspot detection method according to the present invention, driven by a GPU-accelerated lithography simulator, eliminates the requirement for dataset-dependent hyperparameters, while simultaneously significantly improving flexibility and reducing computational resource consumption.
2. The end-to-end hotspot detection method according to the present invention integrates prior knowledge from lithography simulators into the framework, guiding the hot spot detection model to focus on potential hot spot regions, thereby significantly enhancing interpretability and generalization capability.

### BRIEF DESCRIPTION OF THE DRAWINGS

FIG. 1 is a schematic flow diagram of a Transformer-based end-to-end hotspot detection method for integrated circuit layouts according to the present invention;

FIG. 2 is a schematic flow diagram of a GPU-accelerated lithography simulator for outputting a post-lithography printed image according to the present invention;

FIG. 3 is a comparative results schematic between embodiments of the present invention and a deep learning-based generic object detection network on the ICCAD 2016 benchmark dataset; and

FIG. 4 is a performance comparison diagram between embodiments of the present invention and existing state-of-the-art methodologies.

### DETAILED DESCRIPTION OF THE EMBODIMENTS

In order to make the objective, technical solution, and advantages of the present invention clearer, the technical solutions of the application are further elaborated below with reference to the accompanying drawings. The described embodiments are only a part of the embodiments related to the present invention. All non-innovative embodiments developed by other researchers in the field based on these embodiments shall fall within the protection scope of the present invention. Additionally, step numbering in the embodiments of the present invention is defined solely for ease of explanation, and no limitation is imposed on the sequence of steps. The execution order of all steps in the embodiments may be adaptively adjusted according to the understanding of those skilled in the art.

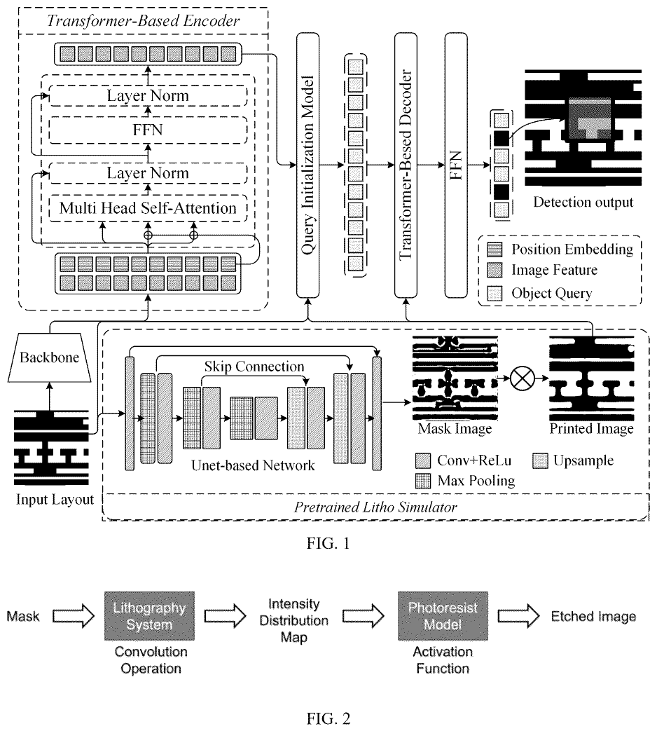

In one embodiment of the present invention, a Transformer-based end-to-end hotspot detection method for integrated circuit layouts, driven by a GPU-accelerated prior lithography simulator, as shown in FIG. 1, including the following steps:
step 1. existing integrated circuit layout data is convered into binary image data and storing the converted binary image data;
step 2. the converted binary image data is input into a GPU-driven lithography simulator, and a post-lithography printed image is output and stored;
step 3. a Transformer-based end-to-end hotspot detector is constructed, both the post-lithography printed image and the original binary image are input into a query vector initialization module for metric measurement, and obtaining positional information of potential hotspots is obtained and stored;
step 4. prior lithography information is generated based on the original binary image and the lithographically processed printed image, a layout training set and a validation set are constructed, the sets are input into the Transformer-based end-to-end hotspot detector for model training, and a trained hotspot detection model is obtained; and
Step 5: the positional information of potential hotspots from a binary image layout of a chip layout to be tested, obtained through Steps 2 and 3, is input into the trained hotspot detection model of step 4 for testing; and hotspots are located within the layout.

In FIG. 1, the model architecture of the embodiment is mainly composed of two parts: a prior lithography simulator and a transformer-based object detector.

The input circuit layout image is processed through the lithography simulator to obtain prior positional information of potential hotspots; simultaneously, the circuit layout image is input into the Transformer-based end-to-end hotspot detector, sequentially passes through a decoder, a query vector initialization module, an encoder, and a feed-forward neural network, whereby the detected chip layout image containing hotspots is output.

In the embodiment, as shown in FIG. 2, the detailed implementation process of step 2 is as follows:
1) In a lithography system, incident light is transmitted through a mask, and spatial information M of the mask pattern is transferred to an optical projection system, whereby an input light intensity distribution is converted into a lithographic intensity distribution on a wafer plane.

The intensity distribution is conventionally represented by an aerial image I, and the entire model can be modeled using Hopkins diffraction theory:

$$I = H ( M ) = {\sum }_{k = 1}^{K} {μ}_{k} {\vert {h}_{k} ⊗ M \vert}^{2}$$

wherein I denotes an intensity distribution aerial image; M denotes spatial information of a mask image; the H function is defined as the Hopkins diffraction function; hₖ denotes a k-th optical kernel function; μₖ denotes a corresponding weight; ⊗ denotes a convolution operation; and K denotes a quantity of convolution kernels;
2) The lithography model converts the aerial image I into a printed pattern Z, the printed pattern Z represents a pattern image of the post-etch wafer, where a region is considered as etched when the lithographic intensity on the wafer plane is greater than the lithography threshold; otherwise no etching occurs:

$$Z ( x , y ) = \{ \begin{matrix}0 & if I ( x , y ) ⩽ {th}_{r} \\ 1 & if I ( x , y ) > t {h}_{r}\end{matrix} ;$$

wherein Z(x,y) denotes coordinates on the photoresist image; I(x,y) denotes coordinates of the aerial image; and th, denotes lithography threshold.
3) In order to implement gradient descent in an iterative learning method, the printed image is represented as:

$$Z ( x , y ) = {σ}_{Z} ( I ( x , y ) ) = \frac{1}{1 + {e}^{( - α ( I ( x , y ) - {I}_{th} ) )}} ;$$

wherein a represents a steepness of a control function, Iₜₕ represents a threshold parameter, configured to control a central inflection point of a Sigmoid function, σ_{Z} denotes a Sigmoid function, configured to input I(x,y), and map the input I(x,y) to an interval of (0,1), thereby forming a smoothed probability value or a normalized output

In the embodiment, a Transformer-based end-to-end hotspot detector is constructed in Step 3, and the structure thereof is as follows:
backbone network: the backbone network of the model in the embodiment is implemented using a ResNet50 architecture for effectively extracting features from an input layout image. The input layout image is processed into a feature map by the backbone network, thereby enabling learning of a two-dimensional representation of the input.

Subsequently, the extracted features are flattened and transmitted to a Transformer encoder for capturing global dependencies, thereby enabling accurate hotspot detection.

Transformer-based encoder: In the model of this embodiment, the Transformer encoder is configured to play a key role in capturing inherent global dependencies and spatial relationships within layout patterns.

A 1×1 convolution is applied to a high-level activation map f derived from the ResNet50 backbone network, whereby the channel number is reduced from C to a smaller dimension d, and a new feature map is obtained. Since the encoder requires sequential input, the spatial dimensions of the feature map are flattened into a d×HW sequence, and the feature map is converted into a series of d-dimensional vectors to allow processing by the Transformer.

Each layer of the Transformer encoder is composed of a multi-head self-attention module and a feed-forward network. The multi-head self-attention mechanism is configured to enable simultaneous attention to different regions of the layout patterns by the model, thereby capturing both local and global contextual information, which is critical for identifying hotspots that are not adjacent but exhibit significant correlations within a global scope.

To process spatial information, fixed positional encodings are further introduced into the Transformer encoder in this embodiment and are added to the input of each attention layer. Thereby, spatial relationships are incorporated into the self-attention mechanism, enabling the model to comprehend layout structures and accurately localize potential hotspot regions.

The feature sequence is processed in parallel by the Transformer encoder, whereby efficient computation is achieved while the capability to detect complex multi-scale hotspot patterns is retained. The features outputted by the encoder incorporate both local features and global contextual information, and are subsequently transmitted to the decoder to accomplish final detection of hotspots.

A Transformer-based decoder: The feature aggregation module of the Transformer-based decoder is configured to leverage prior knowledge derived from lithography simulation to enhance the accuracy of hotspot detection.

At each layer of the Transformer decoder, N object queries are processed in parallel, and the learnable positional embeddings are effectively transformed into predictions of hotspot locations and classifications.

Further, domain-specific knowledge is incorporated through integration of lithography simulation data, ensuring that the object queries are enabled to utilize such knowledge and are focused on regions most susceptible to hotspot occurrences.

The learnable object queries are superimposed with spatially-enhanced information from lithography simulators onto the input of each attention layer, thereby ensuring preservation of spatial awareness and contextual information in the decoder. The embeddings outputted from the decoder are independently transmitted to a feed-forward neural network: the network is configured to predict bounding box coordinates and category labels for each hotspot, ultimately outputting N predictive results.

Feed-Forward Network (FFN): in the model of this embodiment, the FFN is composed of a three-layer perceptron with ReLU activation functions and a network structure with a hidden dimension of d, which is subsequently followed by a linear projection layer. The FFN is utilized to predict the center coordinates, height, and width of each bounding box, while the category labels are output through the linear layer via a softmax operation.

Further, in the present embodiment, the query vector initialization module described in step 3 is defined as a critical component for integrating prior lithographic simulation information into the hotspot detection object detector. The module is configured to partition input layout images and lithographic printing images into non-overlapping blocks, whereby a metric loss for each block is computed to quantify lithographic discrepancies. Specifically, the metric loss is utilized to measure discrepancies between the two images, thereby generating a loss map that highlights critical regions.

In the embodiment, positional information of potential hotspots is obtained in step 3, and the detailed implementation process is as follows:
1) dividing an image: both the input original binary image and the post-lithography printed image are partitioned into a plurality of non-overlapping blocks;
2) for each block B(i,j), a pixel value difference at each pixel location is calculated within the block:

$${L}_{metric} ( i , j ) = {I}_{input} ( p ) - {I}_{print} ( p ) ;$$

wherein Iᵢₙₚᵤₜ(p) and Iₚᵣᵢₙₜ(p) denote pixel intensities at pixel location p in the input original binary image and the lithographically processed printed image, respectively;
3) calculating a metric loss for each block: the metric loss L_{metric}(i,j) is calculated for each block by summing squared differences of all pixels within the block;
4) constructing a loss map: metric losses are aggregated from all blocks, to construct a loss map L_{metric} map, wherein the loss map includes metric loss values of each block;
5) selecting potential hotspot: within a loss map, the top k blocks exhibiting the highest loss values are identified as candidate hotspots, and positional information are preserved corresponding to the candidate hotspots within the blocks; and
6) integrating positional prior information: location data of potential hotspot-containing blocks is conveyed to the decoder as prior knowledge, the model is directed to focus attention toward regions exhibiting significant lithographic disparitie, thereby enhancing hotspot detection accuracy and operational efficiency.

In the testing phase, the specific implementation process of step 5 is configured as follows: generating binary image data of the chip layout to be tested by repeating step 1 processes;
1) binary image data of the layout under test is generated by repeating step 1 processes;
2) a post-lithography printed image is obtained by repeating step 2 processes on the layout under test;
3) the layout under test is processed by repeating step 3, and prior lithographic information is obtained; and
4) the binary original image and the prior lithographic information are input into the hotspot detection model trained in step 4, the positional information of hotspots is output and demarcated, and is defined as the final output result of the model.

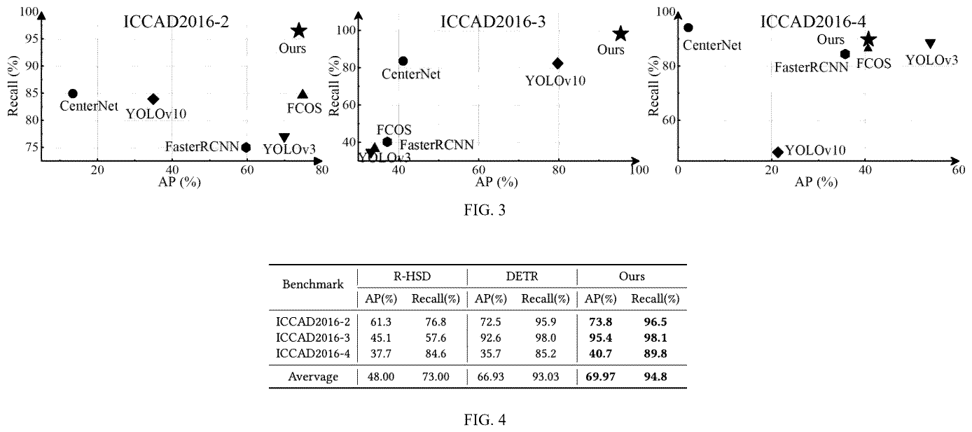

Furthermore, the layout hotspot detection method of the present invention is compared with the deep learning-based general object detection network on the ICCAD2016 dataset, and the result is shown in FIG. 3.

As can be observed from FIG. 3, on the ICCAD2016-2 and ICCAD2016-3 datasets, the method proposed in the present invention achieves significant leads in both precision and recall rates over mainstream general object detection model frameworks. On the ICCAD2016-4 dataset, although the precision is lower than the YOLOv3 model and the recall rate is inferior to CenterNet, in terms of combined precision and recall rates, the method proposed in the present invention is still demonstrated to be superior to mainstream general object detection model frameworks.

Furthermore, the chip layout hotspot detection method of the present invention is compared with the state-of-the-art method, and the comparison is shown in FIG. 4, where the state-of-the-art method is the R-HSD model.

As can be seen from FIG. 4, the method of the present invention is superior to the state-of-the-art method R-HSD in both precision and recall rate, and a 3.04% improvement in precision and a 1.77% improvement in recall rate are achieved based on the baseline model DETR.

In the embodiment, the present invention further provides an electronic device, including:
one or more processors; and a storage device having one or more programs stored thereon; wherein the one or more programs, when executed by the one or more processors, cause the one or more processors to implement the Transformer-based end-to-end chip layout hotspot detection method.

The above descriptions are only preferred embodiments of the present invention. It is to be noted that: by those of ordinary skill in the art, without departing from the principles of the present invention, modifications and refinements may still be made, and these modifications and refinements shall be regarded as falling within the protection scope of the present invention.

What is claimed is:

1. A Transformer-based end-to-end hotspot detection method for integrated circuit layouts, comprising the following steps:
step 1. converting existing integrated circuit layout data into binary image data and storing the converted binary image data;
step 2. inputting the converted binary image data into a GPU-driven lithography simulator, and outputting a post-lithography printed image and storing; and
step 3. constructing a Transformer-based end-to-end hotspot detector, and inputting both the post-lithography printed image and an original binary image into a query vector initialization module for performing metric measurement, thereby obtaining positional information of potential hotspots, and storing;
wherein the obtaining the positional information of the potential hotspots comprises the following steps:
step 3.1. dividing the input original binary image and the post-lithography printed image into a plurality of non-overlapping blocks;
step 3.2. calculating, for each block B(i,j), a pixel value difference at each pixel location within the blocks:
$$D ( i , j , x , y ) = {I}_{input} ( p ) - {I}_{print} ( p )$$
wherein Iᵢₙₚᵤₜ(p) and Iₚᵣᵢₙₜ(p) denote pixel intensities at pixel location p in the input original binary image and the post-lithography printed image, respectively;
step 3.3. calculating a metric loss for each patch: calculating a metric loss L_{metric}(i,j) for each block by summing squared differences of all pixels within the patches, as defined by the following formula:
$${L}_{metric} ( i , j ) = {\sum }_{x = 0}^{N - 1} {\sum }_{y = 0}^{N - 1} {D ( i , j , x , y )}^{2} ;$$
wherein N denotes a block size, and (i,j) denotes a block index;
step 3.4. constructing a loss map: aggregating metric losses from all blocks, to construct a loss map L_{metric map}, wherein the loss map comprises metric loss values of each block;
step 3.5. selecting the potential hotspots: identifying, within the loss map, top k blocks exhibiting highest loss values as the potential hotspots, and preserving the positional information corresponding to the potential hotspots within the blocks;
step 3.6. integrating positional prior information: conveying location data of potential hotspot-containing blocks to a decoder as prior knowledge, directing decoder's attention toward regions exhibiting significant lithographic disparitie, thereby enhancing hotspot detection accuracy and operational efficiency;
step 4. constructing, according to prior lithography information obtained from the original binary image and the post-lithography printed image, a layout training set and a validation set of a layout, inputting the sets into the Transformer-based end-to-end hotspot detector for model training, thereby obtaining a trained hotspot detection model; and
step 5. inputting an integrated circuit layout under test, according to the positional information of the potential hotspots in a binary image layout obtained through step 2 and step 3, into the trained hotspot detection model of step 4 for testing; and locating hotspots within the layout.

2. The Transformer-based end-to-end hotspot detection method for the integrated circuit layouts according to claim 1, wherein in the step 2, the GPU-driven lithography simulator performs processing operations comprises the following steps:
step 2.1. transferring, in the lithography simulator, spatial information of a mask image to an optical projection system via incident light passing through a mask, and converting an input light intensity distribution into a lithographic intensity distribution on a wafer plane, which represented as follow;
$$I = H ( M ) = {\sum }_{k = 1}^{K} {μ}_{k} {\vert {h}_{k} ⊗ M \vert}^{2} ;$$
wherein, I represents an intensity distribution aerial image, M represents the spatial information of the mask image, H function represents Hopkins diffraction function; hₖ represents a k-th optical kernel function, μₖ represents a corresponding weight, ⊗ represents a convolution operation, K represents a quantity of convolution kernels;
step 2.2. converting an aerial image I into a printed pattern Z through the lithography simulator, wherein the printed pattern Z represents a pattern image of a post-etch wafer, regions on a wafer surface where a photolithographic intensity exceeds a predetermined lithographic threshold are defined as etched areas, whereas regions below the threshold undergo no etching:
$$Z ( x , y ) = \{ \begin{matrix}0 & if I ( x , y ) ⩽ {th}_{r} \\ 1 & if I ( x , y ) > t {h}_{r}\end{matrix}$$
wherein Z(x,y) represents coordinates on a photoresist pattern, I(x,y) represents coordinates of an aerial image, and thᵣ represents lithographic threshold;
step 2.3. the printed pattern Z is represented as:
$$Z ( x , y ) = {σ}_{Z} ( I ( x , y ) ) = \frac{1}{1 + {e}^{( - α ( I ( x , y ) - {I}_{th} ) )}}$$
wherein a represents a steepness of a control function, Iₜₕ represents a threshold parameter, configured to control a central inflection point of a Sigmoid function, σ_{Z} denotes the Sigmoid function, configured to input I(x,y), and map the input I(x,y) to an interval of (0,1); and
outputting the pattern Z as the post-lithography printed image and performing gradient descent within an iterative learning method.

3. The Transformer-based end-to-end hotspot detection method for the integrated circuit layouts according to claim 1, wherein in the step 3, the transformer-based end-to-end hotspot detector sequentially comprises: a backbone network, an encoder, the query vector initialization module, the decoder, and a feed-forward neural network;
wherein the backbone network, employing an ResNet50 architecture, is configured to: process an input layout image into a feature map; learn a two-dimensional representation of the input layout image through feature extraction; flatten extracted features into a high-level activation map; and transmit the high-level activation map to the encoder;
the encoder is a Transformer-based encoder, which is configured to capture global dependencies and spatial relationships in semiconductor layout patterns, generate a new feature map, and transmit the new feature map to the decoder;
the decoder, configured as a Transformer-based decoder, processing N target queries in parallel at each layer via a feature aggregation module, incorporating prior knowledge from lithography simulation into an input of each attention layer, outputting N predictive results, and independently transmitting each of the N prediction results to a feedforward neural network.

4. The Transformer-based end-to-end hotspot detection method for the integrated circuit layouts according to claim 3, wherein in the step 3, the query vector initialization module is configured to divide the input post-lithography printed image and the original binary image into the non-overlapping blocks, calculate the metric loss for each block, and integrate lithographic simulation prior information into critical components of the Transformer-based end-to-end hotspot detector; wherein metric loss measure discrepancies between the two images, generate a discrepancy map, and visually emphasize critical regions.

5. The Transformer-based end-to-end hotspot detection method for the integrated circuit layouts according to claim 3, wherein each Transformer encoder layer comprises a multi-head self-attention module and the feed-forward neural network, and introduces a fixed positional encoding;
wherein the multi-head self-attention module is configured to simultaneously attend to distinct partitions of the circuit layout, capture localized geometric patterns and global topological dependencies, and identify hotspots that are non-adjacent but exhibit critical correlations within a global context;
the fixed positional encoding is incorporated into an input of each attention layer and is configured to integrate spatial relationships into the multi-head self-attention module, thereby comprehending layout structures and localizing potential hotspot regions; and
each layer of the Transformer encoder processes a feature sequence in parallel, applies a 1×1 convolution to the input high-level activation maps to reduce a number of channels from C to a dimension d, integrates local features with global context to generate a new feature map, converts the feature map into a series of d-dimensional vectors, and transmits the vectors to the decoder.

6. The Transformer-based end-to-end hotspot detection method for the integrated circuit layouts according to claim 5, wherein the feed-forward neural network preferably comprises: a three-layer multilayer perceptron comprising ReLU activation functions, a network with a hidden dimension of d, followed by a linear projection layer configured to predict center coordinates, height, and width of a bounding box for each hotspot, and the linear projection layer is configured to output class labels via a softmax function.

7. The Transformer-based end-to-end hotspot detection method for the integrated circuit layouts according to claim 5, wherein in the step 5, the locating the hotspots in the integrated circuit layout under test comprises the following sub-steps:
step 5.1. repeating step 1 in the integrated circuit layout under test, to obtain binary image data;
step 5.2. repeating step 2 in the integrated circuit layout under test, to obtain a post-lithography printed image;
step 5.3. repeating step 3 in the integrated circuit layout under test, to obtain prior lithography information; and
step 5.4. inputting both the original binary image and prior lithography information into the trained hotspot detection model established in step 4, outputting positional coordinates of hotspots and annotating bounding boxes as final detection results generated by the hotspot detection model.

8. An electronic device, comprising:
one or more processors; and
a storage device having one or more programs stored thereon;
wherein the one or more programs, when executed by the one or more processors, cause the one or more processors to implement the Transformer-based end-to-end hotspot detection method for the integrated circuit layouts according to claim 1.

9. A computer-readable storage medium having a computer program stored thereon, wherein the computer program, when executed by a processor, causes the processor to implement the steps of the Transformer-based end-to-end hotspot detection method for the integrated circuit layouts according to claim 1.

10. The electronic device according to claim 8, wherein in the step 2 of the Transformer-based end-to-end hotspot detection method for the integrated circuit layouts, the GPU-driven lithography simulator performs processing operations comprises the following steps:
step 2.1. transferring, in the lithography simulator, spatial information of a mask image to an optical projection system via incident light passing through a mask, and converting an input light intensity distribution into a lithographic intensity distribution on a wafer plane, which represented as follow;
$$I = H ( M ) = {\sum }_{k = 1}^{K} {μ}_{k} {\vert {h}_{k} ⊗ M \vert}^{2} ;$$
wherein, I represents an intensity distribution aerial image, M represents the spatial information of the mask image, H function represents Hopkins diffraction function; hₖ represents a k-th optical kernel function, μₖ represents a corresponding weight, ⊗ represents a convolution operation, K represents a quantity of convolution kernels;
step 2.2. converting an aerial image I into a printed pattern Z through the lithography simulator, wherein the printed pattern Z represents a pattern image of a post-etch wafer, regions on a wafer surface where a photolithographic intensity exceeds a predetermined lithographic threshold are defined as etched areas, whereas regions below the threshold undergo no etching:
$$Z ( x , y ) = \{ \begin{matrix}0 & if I ( x , y ) ⩽ {th}_{r} \\ 1 & if I ( x , y ) > t {h}_{r}\end{matrix}$$
wherein Z(x,y) represents coordinates on a photoresist pattern, I(x,y) represents coordinates of an aerial image, and th, represents lithographic threshold;
step 2.3. the printed pattern Z is represented as:
$$Z ( x , y ) = {σ}_{Z} ( I ( x , y ) ) = \frac{1}{1 + {e}^{( - α ( I ( x , y ) - {I}_{th} ) )}}$$
wherein a represents a steepness of a control function, Iₜₕ represents a threshold parameter, configured to control a central inflection point of a Sigmoid function, σ_{Z} denotes the Sigmoid function, configured to input I(x,y), and map the input I(x,y) to an interval of (0,1); and
outputting the pattern Z as the post-lithography printed image and performing gradient descent within an iterative learning method.

11. The electronic device according to claim 8, wherein in the step 3 of the Transformer-based end-to-end hotspot detection method for the integrated circuit layouts, the transformer-based end-to-end hotspot detector sequentially comprises: a backbone network, an encoder, the query vector initialization module, the decoder, and a feed-forward neural network;
wherein the backbone network, employing an ResNet50 architecture, is configured to: process an input layout image into a feature map; learn a two-dimensional representation of the input layout image through feature extraction; flatten extracted features into a high-level activation map; and transmit the high-level activation map to the encoder;
the encoder is a Transformer-based encoder, which is configured to capture global dependencies and spatial relationships in semiconductor layout patterns, generate a new feature map, and transmit the new feature map to the decoder;
the decoder, configured as a Transformer-based decoder, processing N target queries in parallel at each layer via a feature aggregation module, incorporating prior knowledge from lithography simulation into an input of each attention layer, outputting N predictive results, and independently transmitting each of the N prediction results to a feedforward neural network.

12. The electronic device according to claim 11, wherein in the step 3 of the Transformer-based end-to-end hotspot detection method for the integrated circuit layouts, the query vector initialization module is configured to divide the input post-lithography printed image and the original binary image into the non-overlapping blocks, calculate the metric loss for each block, and integrate lithographic simulation prior information into critical components of the Transformer-based end-to-end hotspot detector; wherein metric loss measure discrepancies between the two images, generate a discrepancy map, and visually emphasize critical regions.

13. The electronic device according to claim 11, wherein in the Transformer-based end-to-end hotspot detection method for the integrated circuit layouts, each Transformer encoder layer comprises a multi-head self-attention module and the feed-forward neural network, and introduces a fixed positional encoding;
wherein the multi-head self-attention module is configured to simultaneously attend to distinct partitions of the circuit layout, capture localized geometric patterns and global topological dependencies, and identify hotspots that are non-adjacent but exhibit critical correlations within a global context;
the fixed positional encoding is incorporated into an input of each attention layer and is configured to integrate spatial relationships into the multi-head self-attention module, thereby comprehending layout structures and localizing potential hotspot regions; and
each layer of the Transformer encoder processes a feature sequence in parallel, applies a 1×1 convolution to the input high-level activation maps to reduce a number of channels from C to a dimension d, integrates local features with global context to generate a new feature map, converts the feature map into a series of d-dimensional vectors, and transmits the vectors to the decoder.

14. The electronic device according to claim 13, wherein in the Transformer-based end-to-end hotspot detection method for the integrated circuit layouts, the feed-forward neural network preferably comprises: a three-layer multilayer perceptron comprising ReLU activation functions, a network with a hidden dimension of d, followed by a linear projection layer configured to predict center coordinates, height, and width of a bounding box for each hotspot, and the linear projection layer is configured to output class labels via a softmax function.

15. The electronic device according to claim 13, wherein in the step 5 of the Transformer-based end-to-end hotspot detection method for the integrated circuit layouts, the locating the hotspots in the integrated circuit layout under test comprises the following sub-steps:
step 5.1. repeating step 1 in the integrated circuit layout under test, to obtain binary image data;
step 5.2. repeating step 2 in the integrated circuit layout under test, to obtain a post-lithography printed image;
step 5.3. repeating step 3 in the integrated circuit layout under test, to obtain prior lithography information; and
step 5.4. inputting both the original binary image and prior lithography information into the trained hotspot detection model established in step 4, outputting positional coordinates of hotspots and annotating bounding boxes as final detection results generated by the hotspot detection model.

16. The computer-readable storage medium according to claim 9, wherein in the step 2 of the Transformer-based end-to-end hotspot detection method for the integrated circuit layouts, the GPU-driven lithography simulator performs processing operations comprises the following steps:
step 2.1. transferring, in the lithography simulator, spatial information of a mask image to an optical projection system via incident light passing through a mask, and converting an input light intensity distribution into a lithographic intensity distribution on a wafer plane, which represented as follow;
$$I = H ( M ) = {\sum }_{k = 1}^{K} {μ}_{k} {\vert {h}_{k} ⊗ M \vert}^{2} ;$$
wherein, I represents an intensity distribution aerial image, M represents the spatial information of the mask image, H function represents Hopkins diffraction function; hₖ represents a k-th optical kernel function, μₖ represents a corresponding weight, ⊗ represents a convolution operation, K represents a quantity of convolution kernels;
step 2.2. converting an aerial image I into a printed pattern Z through the lithography simulator, wherein the printed pattern Z represents a pattern image of a post-etch wafer, regions on a wafer surface where a photolithographic intensity exceeds a predetermined lithographic threshold are defined as etched areas, whereas regions below the threshold undergo no etching:
$$Z ( x , y ) = \{ \begin{matrix}0 & if I ( x , y ) ⩽ {th}_{r} \\ 1 & if I ( x , y ) > t {h}_{r}\end{matrix}$$
wherein Z(x,y) represents coordinates on a photoresist pattern, I(x,y) represents coordinates of an aerial image, and th, represents lithographic threshold;
step 2.3. the printed pattern Z is represented as:
$$Z ( x , y ) = {σ}_{Z} ( I ( x , y ) ) = \frac{1}{1 + {e}^{( - α ( I ( x , y ) - {I}_{th} ) )}}$$
wherein a represents a steepness of a control function, Iₜₕ represents a threshold parameter, configured to control a central inflection point of a Sigmoid function, σ_{Z} denotes the Sigmoid function, configured to input I(x,y), and map the input I(x,y) to an interval of (0,1); and
outputting the pattern Z as the post-lithography printed image and performing gradient descent within an iterative learning method.

17. The computer-readable storage medium according to claim 9, wherein in the step 3 of the Transformer-based end-to-end hotspot detection method for the integrated circuit layouts, the transformer-based end-to-end hotspot detector sequentially comprises: a backbone network, an encoder, the query vector initialization module, the decoder, and a feed-forward neural network;
wherein the backbone network, employing an ResNet50 architecture, is configured to: process an input layout image into a feature map; learn a two-dimensional representation of the input layout image through feature extraction; flatten extracted features into a high-level activation map; and transmit the high-level activation map to the encoder;
the encoder is a Transformer-based encoder, which is configured to capture global dependencies and spatial relationships in semiconductor layout patterns, generate a new feature map, and transmit the new feature map to the decoder;
the decoder, configured as a Transformer-based decoder, processing N target queries in parallel at each layer via a feature aggregation module, incorporating prior knowledge from lithography simulation into an input of each attention layer, outputting N predictive results, and independently transmitting each of the N prediction results to a feedforward neural network.

18. The computer-readable storage medium according to claim 17, wherein in the step 3 of the Transformer-based end-to-end hotspot detection method for the integrated circuit layouts, the query vector initialization module is configured to divide the input post-lithography printed image and the original binary image into the non-overlapping blocks, calculate the metric loss for each block, and integrate lithographic simulation prior information into critical components of the Transformer-based end-to-end hotspot detector; wherein metric loss measure discrepancies between the two images, generate a discrepancy map, and visually emphasize critical regions.

19. The computer-readable storage medium according to claim 17, wherein in the Transformer-based end-to-end hotspot detection method for the integrated circuit layouts, each Transformer encoder layer comprises a multi-head self-attention module and the feed-forward neural network, and introduces a fixed positional encoding;
wherein the multi-head self-attention module is configured to simultaneously attend to distinct partitions of the circuit layout, capture localized geometric patterns and global topological dependencies, and identify hotspots that are non-adjacent but exhibit critical correlations within a global context;
the fixed positional encoding is incorporated into an input of each attention layer and is configured to integrate spatial relationships into the multi-head self-attention module, thereby comprehending layout structures and localizing potential hotspot regions; and
each layer of the Transformer encoder processes a feature sequence in parallel, applies a 1×1 convolution to the input high-level activation maps to reduce a number of channels from C to a dimension d, integrates local features with global context to generate a new feature map, converts the feature map into a series of d-dimensional vectors, and transmits the vectors to the decoder.

20. The computer-readable storage medium according to claim 19, wherein in the Transformer-based end-to-end hotspot detection method for the integrated circuit layouts, the feed-forward neural network preferably comprises: a three-layer multilayer perceptron comprising ReLU activation functions, a network with a hidden dimension of d, followed by a linear projection layer configured to predict center coordinates, height, and width of a bounding box for each hotspot, and the linear projection layer is configured to output class labels via a softmax function.
